(19) United States
(12) Patent Application Publication
(10) Pub. No.: US 2025/0142732 A1
(43) Pub. Date: May 1, 2025

(54) CONDUCTIVE LINE REPAIRING METHOD

(71) Applicant: DETEKT TECHNOLOGY INC., NEW TAIPEI CITY (TW)

(72) Inventors: YUN-YAO CHIU, NEW TAIPEI CITY (TW); KUN-HENG LIN, TAOYUAN CITY (TW); CHIH-HSUAN CHUANG, CHANGHUA COUNTY (TW)

(21) Appl. No.: 18/494,911

(22) Filed: Oct. 26, 2023

(51) Int. Cl. H05K 3/22; H05K 3/00; H05K 3/24

(52) U.S. Cl. CPC H05K 3/225; H05K 3/0008; H05K 3/246; H05K 2203/0126; H05K 2203/10

(57) ABSTRACT

The present invention discloses a conductive line repairing method, which at least includes the following steps: a placing step, in which an object having at least one line breaking site is placed on a platform unit of a jet-coating module; a jetting step, in which the jet-coating module is operated to jet and coat a conductive material on the line breaking site; and a solidifying step, in which a solidifying module is operated to have the conductive material solidified, wherein the conductive material, after the solidification, makes the line breaking site conducting. In present invention, the conductive material is jetted and coated on the line breaking site of the object and then solidified to repair a circuit having the line breaking site and to resume the function of electrical conduction thereof to thereby reduce rejected products and restore production yield, achieving an effect of environmental protection.

### FIELD OF THE INVENTION

The present invention relates to the technical field of conductive line repairing, and more particularly to a conductive line repairing method that repairs a line breaking site on an object through jetting and coating a conductive material.

### BACKGROUND OF THE INVENTION

With the increasing demand of the general consumers for electronic products, together with the increasing emergence of new electronic products, electronic products that are available today target being light, thin, short, and small and this drives continuous improvement and progress of fabrication processes. I Further, such electronic products are commonly provided with printed circuit boards (PCBs) to serve as a carrier of electronic components for establishing electrical connection among the electronic components.

However, during a fabrication process, the printed circuit boards may be subjected to factors, such as abrasion and impact, during transportation, so as to cause conductive lines on the printed circuit boards to break to form a line breaking site (as shown in FIG. 1), thereby resulting in failure and rejection of the printed circuit boards. Thus, this lowers the production yield and is environmentally unfriendly.

Thus, in view of the above, the present invention aims to provide a conductive line repairing method, which helps alleviate the prior art deficiency to thereby enhance the practicability and utilization thereof in the industry.

### SUMMARY OF THE INVENTION

The primary objective of the present invention is to provide a conductive line repairing method, which jets and coats a conductive material on a line breaking site of an object and then solidifies the conductive material to thereby repair a circuit of the line breaking site and to resume the function of electrical conduction thereof to thereby reduce rejected products and also restoring production yield, and also achieving an effect of environmental protection.

Thus, to achieve the above objective, the present invention provides a conductive line repairing method, which at least comprises the following steps: a placing step, in which an object having at least one line breaking site is placed on a platform unit of a jet-coating module; a jetting step, in which the jet-coating module is operated to jet and coat a conductive material on the line breaking site; and a solidifying step, in which a solidifying module is operated to have the conductive material solidified, wherein the conductive material, after solidification, makes the line breaking site conducting.

In some embodiments, the line breaking site is located on a front surface of the object and extended to a lateral surface, and the jetting step is implemented to jet and coat the conductive material on the line breaking site on the front surface of the object and continuously jet and coat the conductive material to the line breaking site on the lateral surface of the object, and then, the solidifying step is implemented to have the conductive material solidified.

In some embodiments, the line breaking site is located on a front surface of the object and extended through a lateral surface to a back surface, and the jetting step is implemented to first jet and coat the conductive material on the line breaking site on the front surface of the object and gradually jet and coat the conductive material toward the line breaking site on the lateral surface of the object, and then, the solidifying step is implemented to have the conductive material solidified, and then, the object is turned over to have the back surface of the object facing upward and the jetting step is implemented to jet and coat the conductive material on the line breaking site on the back surface of the object and gradually jet and coat the conductive material toward the line breaking site on the lateral surface of the object to have the conductive material interconnected, and then, the solidifying step is implemented to have the conductive material solidified.

In some embodiments, the line breaking site is located on a front surface of the object and extended through a lateral surface to a back surface, and the jetting step is implemented to continuously jet and coat the conductive material on the line breaking site on the front surface of the object and continuously jet and coat the conductive material, as being moved through the lateral surface of the object, toward the line breaking site on the back surface of the object, and then, the solidifying step is implemented to have the conductive material coated on the line breaking site on both the front surface and the back surface of the object solidified.

In some embodiments, before the implementation of the solidifying step, an angle-adjusting step is additionally implemented to dispose a fixture under the object to adjust an angle of the object so as to facilitate the implementation of the solidifying step.

In some embodiments, after completion of the placing step, an aligning step is implemented, wherein the aligning step is implemented by operating an aligning module to acquire an aligning marking provided on the object to carry out position correction.

In some embodiments, after completion of the aligning step, an inspecting step is implemented, wherein the inspecting step is implemented by operating an inspecting module to identify a location of the line breaking site, and after completion of the inspecting step, the jetting step is implemented to have the jet-coating module moved to the line breaking site to jet and coat the conductive material.

In some embodiments, after completion of the aligning step, an inspecting step is implemented, wherein the inspecting step is implemented by operating a computer module to display the object for allowing a user to identify, by means of the computer module, a location of the line breaking site and to set up, at the location of the line breaking site, a starting position and a terminating position for jetting and coating performed by the jet-coating module, and then, the jetting step is implemented by having the jet-coating module moved to the starting position to jet and coat the conductive material and to stop jetting and coating at the terminating position.

In some embodiments, the platform unit comprises a porous ceramic table, and the object is placed on the porous ceramic table, and the porous ceramic table is operable to suck and hold the object.

In some embodiments, the jet-coating module is operable to jet and coat the conductive material by means of aerosol jet, nano jet, ink jet, piezoelectric jet, dispenser, u-pipette, or multi-axis jet printing.

In some embodiments, the conductive material comprises a metallic paste.

In some embodiments, the metallic paste comprises one of silver paste, copper paste, gold paste, and nickel paste.

In some embodiments, the solidifying module comprises one of an ultraviolet solidifying module, an infrared solidifying module, a laser solidifying module, a pulse photon solidifying module, and a baking oven module.

### BRIEF DESCRIPTION OF THE DRAWINGS

FIG. 1 is a schematic view showing an object having a line breaking site;

FIG. 2 is a flow chart of a conductive line repairing method according to the present invention;

FIG. 3 is a schematic view showing a first example of implementation of the conductive line repairing method according to the present invention;

FIG. 4 is a schematic view showing a first repairing completed condition of implementation of the conductive line repairing method according to the present invention;

FIG. 5 is a schematic view showing a second example of implementation of the conductive line repairing method according to the present invention;

FIG. 6 is a schematic view showing a second repairing completed condition of implementation of the conductive line repairing method according to the present invention;

FIG. 7 is a schematic view showing a third example of implementation of the conductive line repairing method according to the present invention;

FIG. 8 is a schematic view showing a fourth example of implementation of the conductive line repairing method according to the present invention;

FIG. 9 is a schematic view showing a third repairing completed condition of implementation of the conductive line repairing method according to the present invention;

FIG. 10 is a perspective view showing a jet-coating module that is applicable to implementation of the conductive line repairing method according to the present invention;

FIG. 11 is another flow chart of the conductive line repairing method according to the present invention;

FIG. 12 is a schematic view showing an aligning step and an inspecting step implemented in the conductive line repairing method according to the present invention; and

FIG. 13 is another schematic view showing an aligning step and an inspecting step implemented in the conductive line repairing method according to the present invention.

### DETAILED DESCRIPTION OF THE PREFERRED EMBODIMENTS

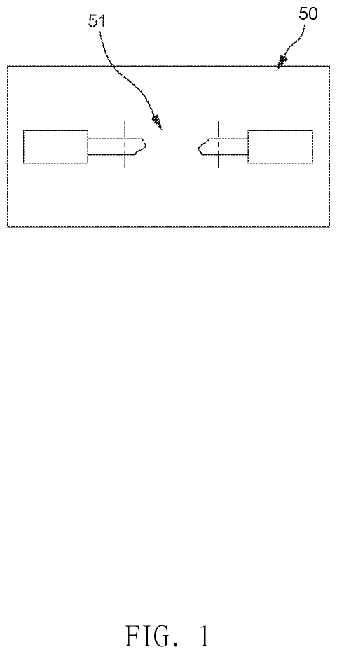

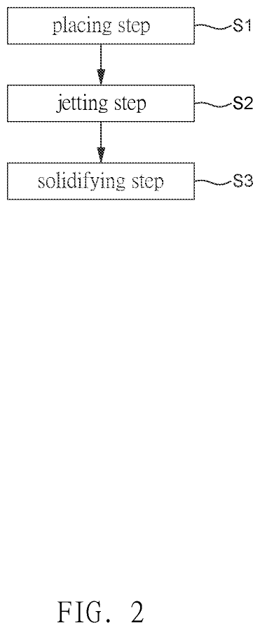

The following provides a description to an embodiment of the present invention with reference to FIGS. 1-13. The description is provided not for intending to limit the way of implementing the present invention and is instead just one of feasible embodiments of the present invention.

Firstly, referring jointly to FIGS. 1-4, the present invention provides a conductive line repairing method, which at least comprises the following steps: a placing step S1, in which an object 50 (such as a printed circuit board) having a line breaking site 51 is placed on a platform unit 11 of a jet-coating module 10; a jetting step S2, in which the jet-coating module 10 is operated to jet and coat a conductive material 20 on the line breaking site 51; and a solidifying step S3, in which a solidifying module 30 is operated to solidify the conductive material 20, wherein the conductive material 20, after the solidification, makes the line breaking site 51 conducting.

However, the line breaking site 51 may be located on a front surface of the object 50, or extending from a front surface to a lateral surface of the object 50, or located on a front surface of the object 50 and extending through a lateral surface to a back surface, and consequently, the conductive line repairing method is partly modified to correspondingly handle line breaking sites 51 at different locations.

Details are provided below:

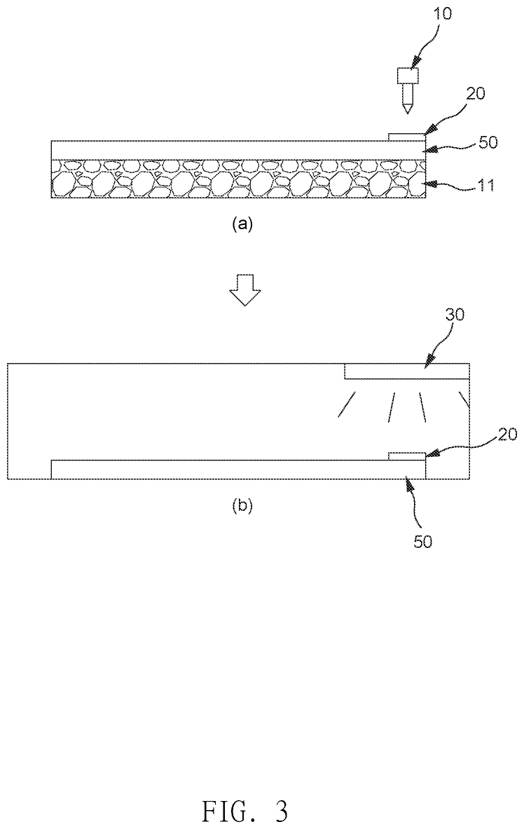

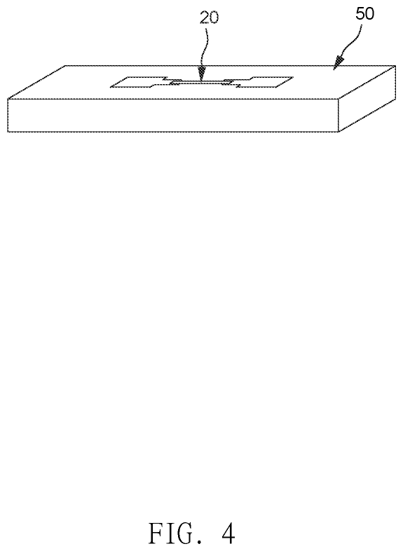

For a line breaking site 51 located on a front surface of the object 50, as shown in FIG. 3, the jetting step S2 is implemented to jet and coat the conductive material 20 on the line breaking site 51 on the front surface of the object 50, and then, the solidifying step S3 is implemented to have the conductive material 20 solidified, and the result achieved after the repairing is shown in FIG. 4.

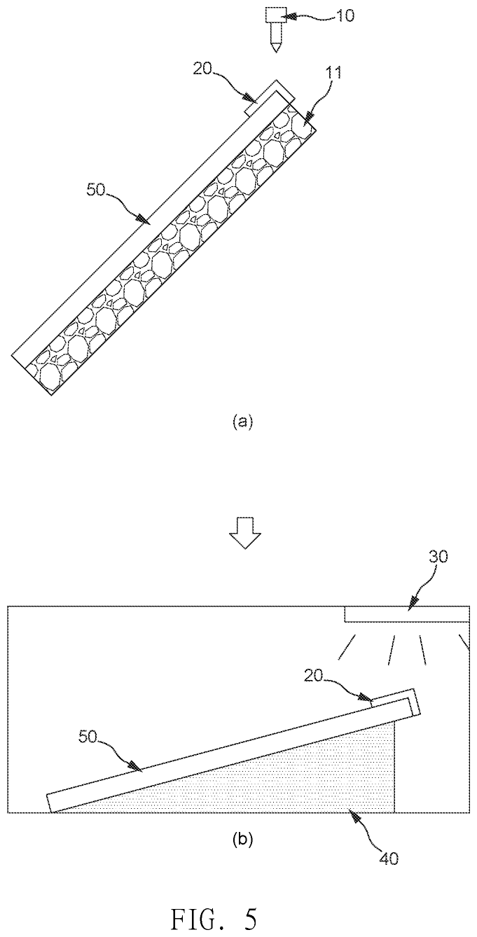

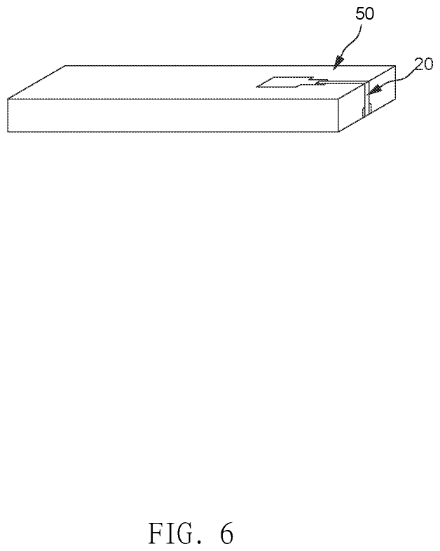

For a line breaking site 51 located on a front surface of the object 50 and extended to a lateral surface, as shown in FIG. 5, the jetting step S2 is implemented to jet and coat the conductive material 20 on the line breaking site 51 on the front surface of the object 50 and continuously jet and coat the conductive material 20 on the line breaking site 51 on the lateral surface of the object 50, and then, the solidifying step S3 is implemented to have the conductive material 20 solidified, and the result achieved after the repairing is shown in FIG. 6.

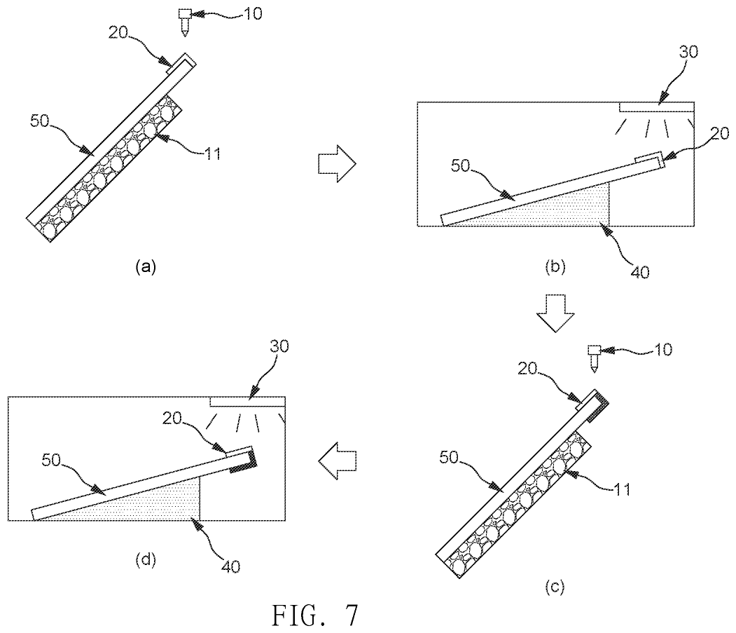

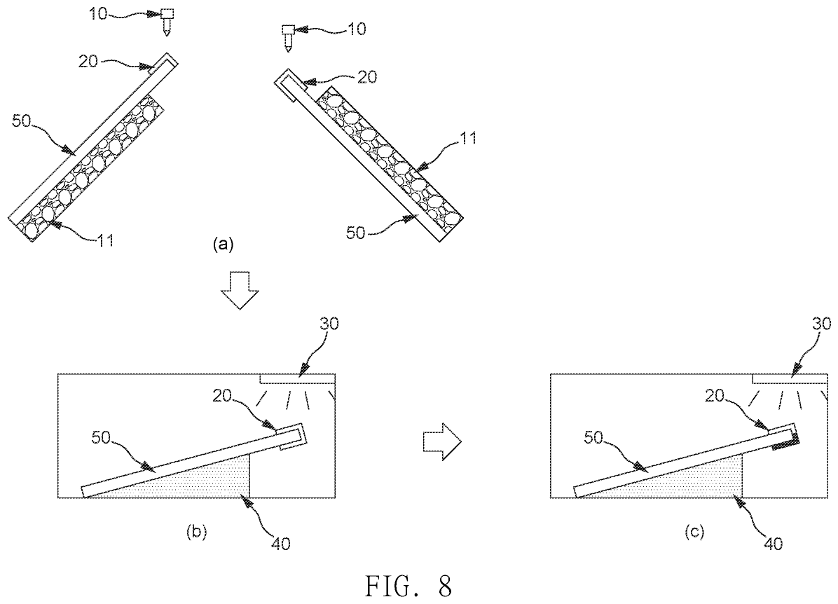

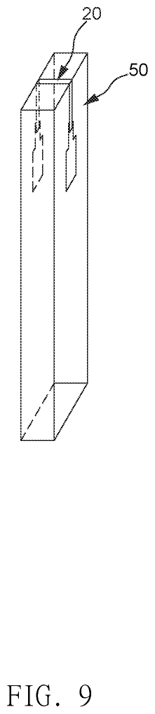

For a line breaking site 51 located on the front surface of the object 50 and extended through a lateral surface to a back surface, as shown in FIG. 7, the jetting step S2 is implemented to first jet and coat the conductive material 20 on the line breaking site 51 on the front surface of the object 50 and gradually jet and coat the conductive material 20 toward the line breaking site 51 on the lateral surface of the object 50, and then, the solidifying step S3 is implemented to have the conductive material 20 solidified, and then, the object 50 is turned over to have the back surface of the object 50 facing upward and the jetting step S2 is implemented to jet and coat the conductive material 20 on the line breaking site 51 on the back surface of the object 50 and gradually jet and coat the conductive material 20 toward the line breaking site 51 on the lateral surface of the object 50 to have the conductive material 20 interconnected, and then, the solidifying step S3 is implemented to have the conductive material 20 solidified; or, alternatively, as shown in FIG. 8, the platform unit 11 of the jet-coating module 10 possesses a function of turning over and thus, in the jetting step S2, the conductive material 20 is jetted and coated on the line breaking site 51 on the front surface of the object 50 and the conductive material 20 is successively jetted and coated, as being moved through the lateral surface of the object 50, toward the line breaking site 51 on the back surface of the object 50, and then, the solidifying step S3 is implemented to have the conductive material 20 coated on the line breaking site 51 on both the front surface and the back surface of the object 50 solidified, and the result achieved after the repairing is shown in FIG. 9.

Further, for the line breaking site 51 located on the front surface of the object 50 and extending through the lateral surface to the back surface, before the solidifying step S3 implemented, an angle-adjusting step is further included, in which a fixture 40 is disposed under the object 50 to adjust an angle of the object 50 in order to promote the performance of the solidifying step S2.

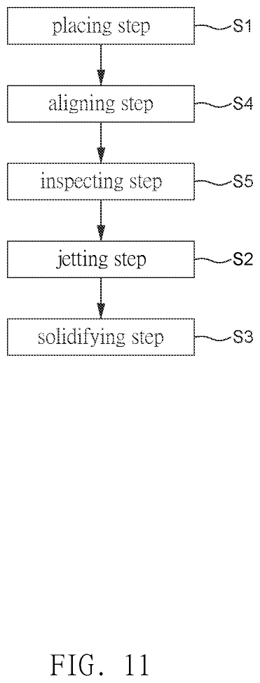

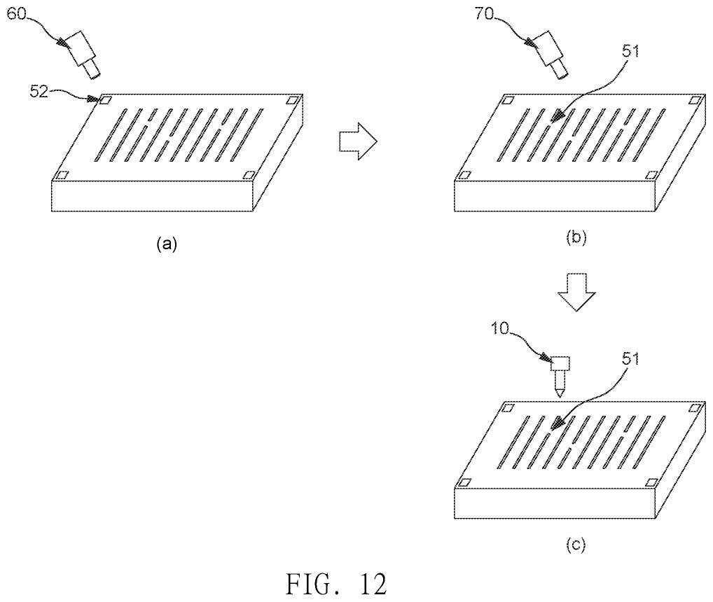

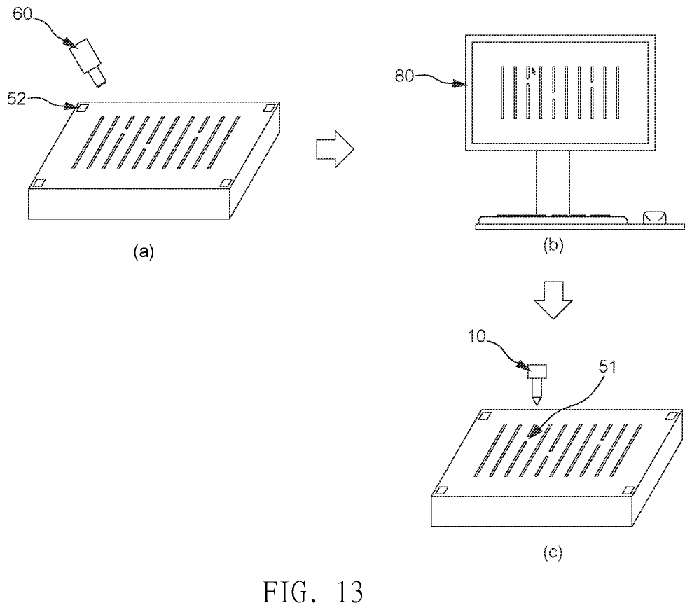

Next, referring to FIGS. 11-13, in any one of the above-described processes for repairing, after completion of the placing step S1, an aligning step S4 may be implemented, either earlier or later, in which the aligning step S4 is implemented by operating an aligning module 60 to acquire an aligning marking 52 provided on the object 50 to carry out position correction. After completion of the aligning step S4, an inspecting step S5 is implemented, as shown in FIG. 12, and the inspecting step S5 is implemented by operating an inspecting module 70 (such as an automatic optic inspection system) to identify the location of the line breaking site 51, wherein the inspecting module 70 is moved, according to coordinate data received thereby, directly to the line breaking site 51 to carry out identification, or alternatively, the inspecting module 70 is operated to scan and thus search the location of the line breaking site 51, and after completion of the inspecting step S5, the jetting step S2 is implemented to have the jet-coating module 10 moved to the line breaking site 51 to jet and coat the conductive material 20; or alternatively, after the completion of the aligning step S4, an inspecting step S5 is implemented, as shown in FIG. 13, and the inspecting step S5 is implemented by operating a computer module 80 to display the object 50 to allow a user to identify, by means of the computer module 80, the location of the line breaking site 51 and to set up, at the location of the line breaking site 51, a coating staring position and terminating position for jetting and coating performed by the jet-coating module 10, and then, the jetting step S2 is implemented by having the jet-coating module 10 moved to the starting position to jet and coat the conductive material 20 and to stop jetting and coating at the terminating position.

Further, the jet-coating module 10 and the solidifying module 30 used in the conductive line repairing method according to the present invention can be collaboratively operated as desired by the user and are not limited to the examples provided below:

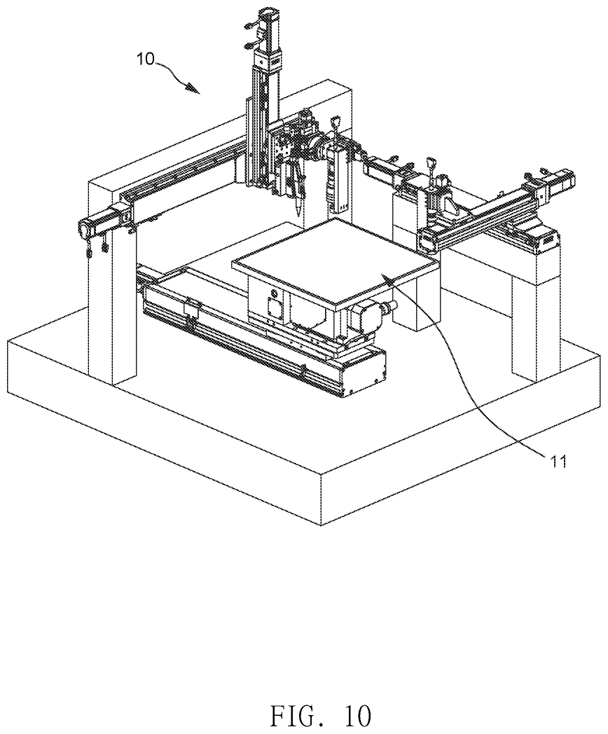

The jet-coating module 10 may apply aerosol jet, nano jet, ink jet, piezoelectric jet, dispenser, u-pipette, or multi-axis jet printing to jet and coat the conductive material 20, and preferably, the conductive material 20 comprises a metallic paste, and the metallic paste includes silver paste, copper paste, gold paste, or nickel paste. For example, in the jetting step S1, the jet-coating module 10 can be a five-axis printing machine (as shown in FIG. 10), and the five-axis printing machine is provided with the platform unit 11 that comprises a porous ceramic table, so that when the object 50 is placed on the porous ceramic table, the porous ceramic table is operated to suck and hold the object 50 to prevent the object 50 from sliding or falling during jetting and coating of the conductive material 20.

The solidifying module 30 can be an ultraviolet solidifying module, an infrared solidifying module, a laser solidifying module, a pulse photon solidifying module, or a baking oven module.

Thus, in summary, as shown in FIG. 3, the conductive line repairing method may be conducted by applying a five-axis printing machine to jet and coat silver paste on a line breaking site 51 on a front surface of an object 50, and then applying a pulse photon solidifying module to solidify the silver paste to thus make the line breaking site 51 conducting to thereby complete repairing; further, as shown in FIG. 5, the conductive line repairing method may be conducted by applying a five-axis printing machine to jet and coat silver paste on a line breaking site 51 on a front surface of an object 50 toward a lateral surface, and then applying a pulse photon solidifying module to solidify the silver paste to thus make the line breaking site 51 conducting to thereby complete repairing; or alternatively, as shown in FIG. 7, the conductive line repairing method may be conducted by applying a five-axis printing machine to jet and coat silver paste on line breaking site 51 on the front surface of an object 50 toward a lateral surface, and then disposing a fixture 40 the object 50 and adjusting an angle of the object 50, and applying a pulse photon solidifying module to solidify the silver paste and turning over the object 50 after the solidification of the silver paste to have a back surface of the object 50 facing upward, and applying the five-axis printing machine to jet and coat silver paste on the line breaking site 51 on the back surface of the object 50 in such a way as to make jetting and coating gradually approach to the silver paste solidified on the lateral surface to have the silver paste interconnected, and then, disposing the fixture 40 under the object 50 and adjusting an angle of the object 50 and re-applying the pulse photon solidifying module to solidify the silver paste to thus make the line breaking site 51 conducting to thereby complete repairing; or alternatively, as shown in FIG. 8, the conductive line repairing method may be conducted by applying a five-axis printing machine in such a way, through operation of turning performed by the platform unit 11, as to continuously jet and coat silver paste on a line breaking site 51 on a front surface and through a lateral surface to a back surface of an object 50, and then disposing a fixture 40 under the object 50 and adjusting an angle of the object 50, and first applying a pulse photon solidifying module to solidify the silver paste on the front surface and the lateral surface of the object 50, and turning the object 50 over, after the solidification of the silver paste, to have the back surface of the object 50 facing upward, and then disposing the fixture 40 under the object 50 and adjusting an angle of the object 50, and then applying the pulse photon solidifying module to solidify the silver paste on the back surface of the object 50 to thus make the line breaking site 51 conducting to thereby complete repairing.

As such, the present invention actually provides a conductive line repairing method, in which a conductive material is jetted and coated on a line breaking site of an object, and the conductive material is solidified, so as to achieve repairing of a circuit including the line breaking site and to resume the function of electrical conduction thereof to thereby reduce rejected products and also restoring production yield, and also achieving an effect of environmental protection.

The description provided above only illustrates the preferred embodiments of the present invention and is not intended to limit the scope of the present invention as defined in the claims. Equivalent alterations and modifications that are made according to the claims and the specification of the present invention should be considered equally falling in the scope of the present invention defined by the claims.

What is claimed is:

1. A conductive line repairing method, at least comprising the following steps:
a placing step, in which an object having at least one line breaking site is placed on a platform unit of a jet-coating module;
a jetting step, in which the jet-coating module is operated to jet and coat a conductive material on the line breaking site; and
a solidifying step, in which a solidifying module is operated to have the conductive material solidified;
wherein the conductive material, after solidification, makes the line breaking site conducting.

2. The conductive line repairing method according to claim 1, wherein the line breaking site is located on a front surface of the object and extended to a lateral surface, and the jetting step is implemented to jet and coat the conductive material on the line breaking site on the front surface of the object and continuously jet and coat the conductive material to the line breaking site on the lateral surface of the object, and then, the solidifying step is implemented to have the conductive material solidified.

3. The conductive line repairing method according to claim 1, wherein the line breaking site is located on a front surface of the object and extended through a lateral surface to a back surface, and the jetting step is implemented to first jet and coat the conductive material on the line breaking site on the front surface of the object and gradually jet and coat the conductive material toward the line breaking site on the lateral surface of the object, and then, the solidifying step is implemented to have the conductive material solidified, and then, the object is turned over to have the back surface of the object facing upward and the jetting step is implemented to jet and coat the conductive material on the line breaking site on the back surface of the object and gradually jet and coat the conductive material toward the line breaking site on the lateral surface of the object to have the conductive material interconnected, and then, the solidifying step is implemented to have the conductive material solidified.

4. The conductive line repairing method according to claim 1, wherein the line breaking site is located on a front surface of the object and extended through a lateral surface to a back surface, and the jetting step is implemented to continuously jet and coat the conductive material on the line breaking site on the front surface of the object and continuously jet and coat the conductive material, as being moved through the lateral surface of the object, toward the line breaking site on the back surface of the object, and then, the solidifying step is implemented to have the conductive material coated on the line breaking site on both the front surface and the back surface of the object solidified.

5. The conductive line repairing method according to claim 2, wherein, before the implementation of the solidifying step, an angle-adjusting step is additionally implemented to dispose a fixture under the object to adjust an angle of the object so as to facilitate the implementation of the solidifying step.

6. The conductive line repairing method according to claim 3, wherein, before the implementation of the solidifying step, an angle-adjusting step is additionally implemented to dispose a fixture under the object to adjust an angle of the object so as to facilitate the implementation of the solidifying step.

7. The conductive line repairing method according to claim 4, wherein, before the implementation of the solidifying step, an angle-adjusting step is additionally implemented to dispose a fixture under the object to adjust an angle of the object so as to facilitate the implementation of the solidifying step.

8. The conductive line repairing method according to claim 1, wherein after completion of the placing step, an aligning step is implemented, wherein the aligning step is implemented by operating an aligning module to acquire an aligning marking provided on the object to carry out position correction.

9. The conductive line repairing method according to claim 8, wherein after completion of the aligning step, an inspecting step is implemented, wherein the inspecting step is implemented by operating an inspecting module to identify a location of the line breaking site, and after completion of the inspecting step, the jetting step is implemented to have the jet-coating module moved to the line breaking site to jet and coat the conductive material.

10. The conductive line repairing method according to claim 8, wherein after completion of the aligning step, an inspecting step is implemented, wherein the inspecting step is implemented by operating a computer module to display the object for allowing a user to identify, by means of the computer module, a location of the line breaking site and to set up, at the location of the line breaking site, a starting position and a terminating position for jetting and coating performed by the jet-coating module, and then, the jetting step is implemented by having the jet-coating module moved to the starting position to jet and coat the conductive material and to stop jetting and coating at the terminating position.

11. The conductive line repairing method according to claim 1, wherein the platform unit comprises a porous ceramic table, and the object is placed on the porous ceramic table, and the porous ceramic table is operable to suck and hold the object.

12. The conductive line repairing method according to claim 1, wherein the jet-coating module is operable to jet and coat the conductive material by means of aerosol jet, nano jet, ink jet, piezoelectric jet, dispenser, u-pipette, or multi-axis jet printing.

13. The conductive line repairing method according to claim 1, wherein the conductive material comprises a metallic paste.

14. The conductive line repairing method according to claim 13, wherein the metallic paste comprises one of silver paste, copper paste, gold paste, and nickel paste.

15. The conductive line repairing method according to claim 1, wherein the solidifying module comprises one of an ultraviolet solidifying module, an infrared solidifying module, a laser solidifying module, a pulse photon solidifying module, and a baking oven module.
